(19) United States
(12) Patent Application Publication
(10) Pub. No.: US 2026/0095164 A1
(43) Pub. Date: Apr. 2, 2026

(54) LOW LOSS VOLTAGE CONTROLLED VARIABLE ATTENUATOR

(71) Applicant: MACOM Technology Solutions Holdings, Inc., Lowell, MA (US)

(72) Inventors: Jean-Marc Mourant, Lowell, MA (US); Amine Lazhar, Lowell, MA (US)

(21) Appl. No.: 19/294,280

(22) Filed: Aug. 8, 2025

Related U.S. Application Data
(60) Provisional application No. 63/701,492, filed on Sep. 30, 2024.

(51) Int. Cl. H03K 5/01; H03K 17/687

(52) U.S. Cl. CPC H03K 5/01; H03K 17/6871

(57) ABSTRACT

Systems, circuits, and methods are provided. An illustrative circuit may include a plurality of attenuator sections, each of the plurality of attenuator sections connected in series with one another between a circuit input and a circuit output, where each of the plurality of attenuator sections includes circuitry to reduce a minimum insertion loss thereof. The circuit may further include a control circuit that provides at least two control signals to each of the plurality of attenuator sections. The first control signal is provided to one or both of a series branch of transistors and a shunt branch of transistors in an attenuator section to move the attenuator section between an on and off state. The second control signal is provided to at least one additional branch of transistors to improve insertion loss of the attenuator section as it transitions between the on and off state.

### CROSS REFERENCE TO RELATED APPLICATION

The present application claims the benefit of and priority to U.S. Provisional Application No. 63/701,492 filed on Sep. 30, 2024, entitled “LOW LOSS VOLTAGE CONTROLLED VARIABLE ATTENUATOR”, which application is incorporated herein by reference in its entirety.

### FIELD OF THE DISCLOSURE

The present disclosure is generally directed toward circuits and, in particular, toward variable gain attenuators, amplifiers, and circuits incorporating the same.

### BACKGROUND

Voltage-controlled Variable Attenuators (VVAs) are commonly used to compensate for slow variations in a communication signal chain (e.g., to compensate for temperature fluctuations). VVAs offer continuous variation, unlike digital step attenuators. Most modulated signals cannot take a sudden step without incurring some amount of distortion.

With high levels of modulations (e.g., 1024 QAM or more), the step would need to be very small. The utilization of a VVA in such a use case would have a step size limited primarily by the Digital-to-Analog Converter (DAC) that drives the VVA. Thus, utilization of a VVA in a highly-modulated signal environment would allow the attenuation to change without distorting the signal.

### SUMMARY

Embodiments of the present disclosure are contemplated to improve the performance of circuits used in connection with VVAs. Illustratively, and without limitation, embodiments of the present disclosure contemplate circuits and/or systems with a Field Effect Transistor (FET)-based circuit used for VVA control.

According to at least some embodiments, a VVA circuit may include a resistive attenuation ladder containing series and shunt FETs to vary the attenuation. Amplifiers may be used to drive the FET gates. Each amplifier may be configured to compare the control signal Vgc to a reference (e.g., a voltage threshold or reference voltage). An illustrative reference voltage (VTi) may be created (e.g., defined for a particular use case) and then increase as i increases from 1 to N (e.g., where N equals the number of attenuator stages in the circuit). As Vgc is increased gradually, more amplifiers change the attenuation of the ladder and the attenuation is also changed gradually and continuously. To realize a smooth attenuation curve, multiple attenuator stages may be controlled at the same time.

Each attenuator stage may be constructed of resistors and FETs that operate as variable resistors and sweep the resistance value from 0 to open. When the FET is fully on or off, the linearity is best. The reason is that the control voltage (VGS) is large, compared to the RF (VDS) voltage applied to the FET. When the FET is on the verge of turning on, the linearity is much worse. The VGS is now small and changing the VDS slightly will change the VGS and the resistance.

To overcome this linearity issue, multiple FETs can be used in series. A given RF voltage can be divided across multiple FETs and the total resistance changes less. The drawback is the additional insertion loss in the attenuator due to the extra FETs. In some attenuator sections, FET stacks can be much larger (e.g., up to 20).

Embodiments of the present disclosure contemplate additional circuitry to reduce the minimum insertion loss. In some embodiments, minimum insertion loss is set by the contributions of the series and the shunt branches. One aspect of the present disclosure is to provide a series branch having two or more FETs in series that are in an on state and which double the on resistance of a single FET. Another aspect of the present disclosure is to provide a shunt branch having two or more FETs that, in an off state, behave like a capacitor. The shunt branch may further include a resistor to load the attenuator if the capacitance is large enough.

Multiple FETs may be used in series to improve linearity at the threshold where the FETs turn on or off. Once this state is departed (e.g., the on or off state is departed), linearity improves dramatically, due to the large VGS control voltage. The number of FETs used may be dependent on the linearity target (e.g., for a given attenuation). For example, at a compression point of 2 Vp across the series branch, a stack of transistors (e.g., two, three, four, or more transistors) could be used and each transistor could handle up to 0.5 Vp. To improve the insertion loss, embodiments of the present disclosure propose adding one or more FET series branches in parallel. However, this additional multi-FET series branch may be subject to different control logic. Specifically, when the multi-FET branch is turning on, this branch is fully off with a large negative control voltage, so it does not degrade linearity. It turns on later (e.g., farther) on the attenuation curve, once the first branch is fully on (e.g., linear) and the voltage across it is small.

It should be noted that a capacitor by itself is not lossy if it can be matched, but that a particular matching (or lack thereof) can add significant losses. In a practical bridge tee attenuator, the shunt resistance may be close to approximately 50 Ohm and a 4 dB stage would be approximately 85 Ohm. If this resistance could be reduced by 5 or 10 Ohm, the loss would be much less. Embodiments of the present disclosure, therefore, contemplate adding a FET branch in parallel to a resistor in the attenuator to short the resistor when it is not used for attenuation. This FET branch may be configured to turn-on farther down the attenuation curve, once the attenuation stage has already turned from max attenuation.

Embodiments of the present disclosure contemplate the incorporation of one, two, or more control lines per attenuation stage. The proposed control lines may be used to control FETs in the VVA such that insertion loss is reduced once the attenuation stage has moved away from a maximum attenuation (e.g., towards a minimum attenuation). In some embodiments, the one or more control lines may include two control lines that are tied together and that are used to offset their control by two attenuation stages to the left. Providing control lines in such a configuration may help ensure that corresponding attenuation stages have already moved from their maximum or highest possible attenuation toward a lower attenuation.

In some embodiments, a circuit is provided that includes: a plurality of attenuator sections, each of the plurality of attenuator sections connected in series with one another between a circuit input and a circuit output, wherein each of the plurality of attenuator sections comprises circuitry to reduce a minimum insertion loss thereof, the circuitry comprising a series branch of transistors, a shunt branch of transistors, and at least one additional branch of transistors connected in parallel with one or both of the series branch of transistors and the shunt branch of transistors, wherein the at least one additional branch of transistors is controllable independent of the series branch of transistors and the shunt branch of transistors; and a control circuit for the plurality of attenuator sections, wherein the control circuit provides at least two control signals to each of the plurality of attenuator sections, wherein a first control signal is provided to one or both of the series branch of transistors and the shunt branch of transistors in an attenuator section to move the attenuator section between an on and off state, and wherein a second control signal is provided to the at least one additional branch of transistors to improve insertion loss of the attenuator section as it transitions between the on and off state.

In some embodiments, a system is provided that includes: a plurality of attenuator sections, each of the plurality of attenuator sections connected in series with one another between a circuit input and a circuit output, wherein each of the plurality of attenuator sections comprises circuitry to reduce a minimum insertion loss thereof, the circuitry comprising a series branch of transistors, a shunt branch of transistors, and at least one additional branch of transistors connected in parallel with one or both of the series branch of transistors and the shunt branch of transistors, wherein the at least one additional branch of transistors is controllable independent of the series branch of transistors and the shunt branch of transistors; and a control circuit for the plurality of attenuator sections, wherein the control circuit comprises a plurality of control stages, wherein each of the plurality of attenuator sections is controlled by two separate control stages in the plurality of control stages such that each of the plurality of attenuator sections receives a first control signal and a second control signal, wherein the first control signal is provided to one or both of the series branch of transistors and the shunt branch of transistors in an attenuator section to move the attenuator section between an on and off state, and wherein the second control signal is provided to the at least one additional branch of transistors to improve insertion loss of the attenuator section as it transitions between the on and off state.

In some embodiments, a method is provided that includes: providing a plurality of attenuator sections, each of the plurality of attenuator sections connected in series with one another between a circuit input and a circuit output, wherein each of the plurality of attenuator sections comprises circuitry to reduce a minimum insertion loss thereof, the circuitry comprising a series branch of transistors, a shunt branch of transistors, and at least one additional branch of transistors connected in parallel with one or both of the series branch of transistors and the shunt branch of transistors, wherein the at least one additional branch of transistors is controllable independent of the series branch of transistors and the shunt branch of transistors; and controlling the plurality of attenuator sections with a plurality of control stages, wherein each of the plurality of attenuator sections is controlled by two separate control stages in the plurality of control stages such that each of the plurality of attenuator sections receives a first control signal and a second control signal, wherein the first control signal is provided to one or both of the series branch of transistors and the shunt branch of transistors in an attenuator section to move the attenuator section between an on and off state, and wherein the second control signal is provided to the at least one additional branch of transistors to improve insertion loss of the attenuator section as it transitions between the on and off state.

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented later.

### BRIEF DESCRIPTION OF THE DRAWINGS

The present disclosure is described in conjunction with the appended figures, which are not necessarily drawn to scale:

FIG. 1 is a diagram illustrating a FET-based VVA circuit;

FIG. 2 is a diagram illustrating an attenuator section usable in a VVA circuit according to at least some embodiments of the present disclosure;

FIG. 3 is a diagram illustrating a control circuit useable for a VVA according to at least some embodiments of the present disclosure; and

FIG. 4 is a flow diagram depicting a process for controlling a VVA circuit in accordance with embodiments of the present disclosure.

### DETAILED DESCRIPTION

It is with respect to the above-noted challenges that embodiments of the present disclosure were contemplated. In particular, a system, circuits, and method of operating such circuits are provided that solve the drawbacks associated with existing mixer circuits.

While embodiments of the present disclosure will primarily be described in connection with mixer circuits used in low-bandwidth applications, it should be appreciated that embodiments of the present disclosure are not so limited. Furthermore, while embodiments of the present disclosure are contemplated for use in mixing MRI imaging signals, it should be appreciated that embodiments of the present disclosure are not so limited.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB).

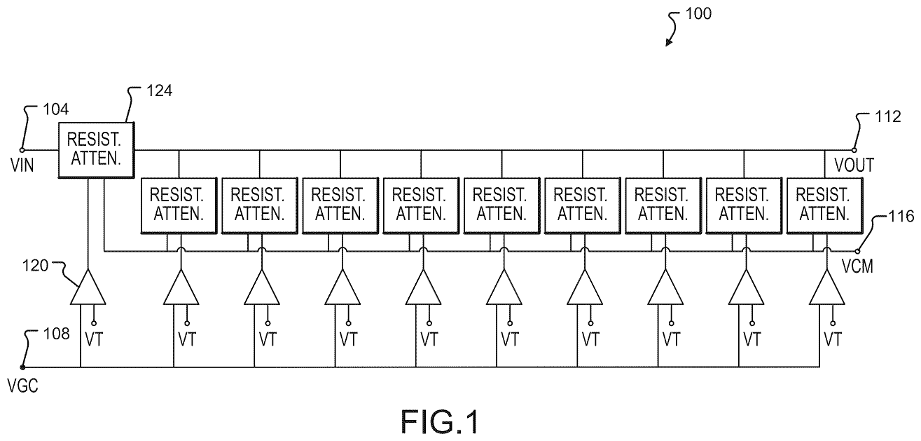

With reference now to FIG. 1, an illustrative circuit 100 is shown. The illustrative circuit 100 represents an example of a differential attenuator circuit 100 that may be improved from aspects of the present disclosure. In particular, the circuit 100 is shown to include a plurality of attenuator sections 124 connected in series between an input 104 and an output 112. The plurality of attenuator sections 124 is shown to include ten attenuator sections 124, which may include internal resistance. The attenuator sections 124 may also be connected to a common mode voltage 116.

Each of the attenuator sections 124 may be controlled by a corresponding differential amplifier 120, which provides a single control voltage to a corresponding attenuator section 124. The differential amplifiers 120 may be connected to a gate control voltage 108 and may compare the inputs provided thereto with a threshold voltage VT.

The first attenuator section 124 may include series MOSFETs, the drains of which function as inputs and the sources of which are respectively connected to the output 112. The second through the tenth attenuator sections 124 may include, respectively, shunt MOSFETs. Resistive sections of the second through tenth attenuator sections 124 may be connected between the output 112 and the common mode voltage 116, and are successively switched into electrical shunt connection between output 112 and common mode voltage 116 in response to the piecewise-linear signals provided by the corresponding differential amplifiers 120.

The differential configuration of the resistive portions of the logarithmic attenuators may provide an improved signal linearity. The improved linearity results because the differential configuration tends to cancel second harmonic distortion. The differential configuration also provides good common mode noise rejection.

The circuit 100 provides the attenuator sections 124 in a resistive attenuation ladder which contains series and shunt FETs to vary the attenuation. As noted above, the differential amplifiers 120 are used to drive the FET gates in the attenuator sections 124. Each amplifier 120 compares the control signal Vgc 108 to the reference voltage VT, which increases as i increases from 1 to 10, in the depicted embodiment. As Vgc 108 is increased gradually, more amplifiers change the attenuation of the ladder and the attenuation is also changed gradually and continuously. To get a smooth attenuation curve, multiple attenuator stages are controlled at the same time.

Each attenuator section 124 includes resistors and FETs that operate as variable resistors and sweep the resistance value from 0 to open. When the FET is fully on or off, the linearity of the attenuator section 124 is best. The reason is that the control voltage 108 is large, compared to the RF (VDS) voltage applied to the FET. When the FET is on the verge of turning on, the linearity is much worse. The control voltage 108 is now small and changing the VDS slightly will change the VGS and the resistance.

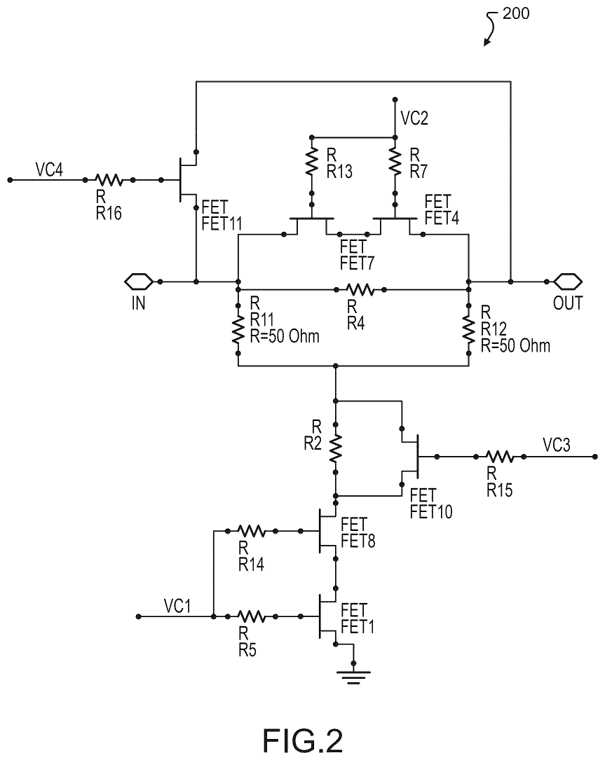

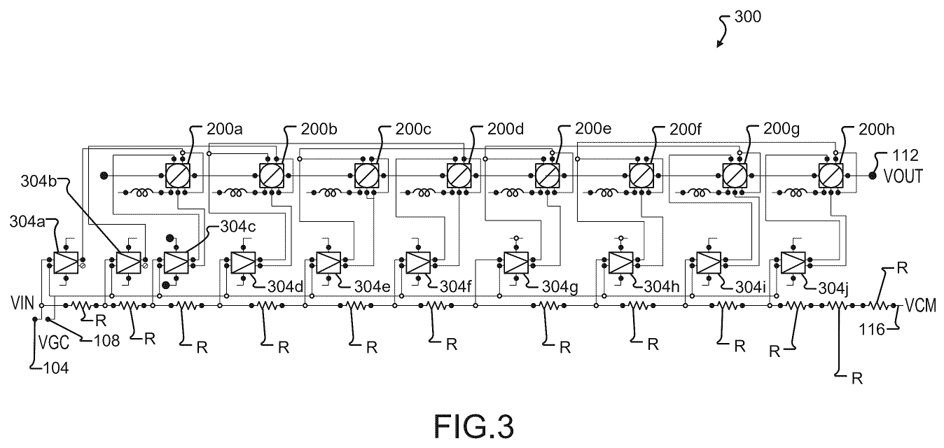

Referring now to FIG. 2, additional details of an improved attenuator section 200 will be described in accordance with at least some embodiments of the present disclosure. The attenuator section 200 may be provided as a replacement for attenuator section 124, which may provide an example of a circuit 300 illustrated in FIG. 3.

The attenuator section 200 is similar to an attenuator section 124, but includes additional circuitry to reduce the minimum insertion loss. In a traditional attenuator section 124, the minimum insertion loss is set by the contributions of the series and the shunt branches. As shown in FIG. 2, the attenuator section 200 may include a series branch having at least two FETs in series in the on state (e.g., FET 7 and FET4), which double the on resistance of a single FET. The attenuator section 200 may also include a shunt branch having at least two FETs (e.g., FET1 and FET8) in the off state that behave like a capacitor. The resistor R2 can still load the attenuator if the capacitance is large enough.

It is noted that the reason multiple FETs are provided in series is that linearity is desired to be improved at the threshold where the FETs turn on or off. Once this point is departed (e.g., the on or off state), linearity improves dramatically, due to the large control voltage 108. The number of FETs used is dependent on the linearity target (e.g., for a given attenuation). For example, at a compression point of 2 Vp across the series branch, a stack of 4 transistors would be beneficial and each transistor could handle up to 0.5 Vp.

To improve the insertion loss, the attenuator section 200 is provided to include a single FET series branch in parallel with the first one (e.g., FET11). However, this branch is controlled differently. When the multi-FET branch is turning on, this new branch (e.g., the branch containing FET11) is fully off with a large negative control voltage, so it does not degrade linearity. The branch may turn on later (or farther) on the attenuation curve, once the first branch is fully on (and linear) and the voltage across it is small.

It should also be noted that a capacitor by itself is not lossy if it can be matched, but that a resistance close to 50 Ohm will add significant loss. The farther from 50 Ohm, the less loss will be added. In a practical bridge tee attenuator, the shunt resistance may be close to 50 Ohm (e.g., a 4 dB stage would be 85 Ohm). If resistance can be reduced to 5 or 10 Ohm, the loss would be much less. Similar to above, an additional FET branch is added (e.g., FET10) in parallel to resistor R2 to short the resistor R2 it when it is not used for attenuation. As before, this branch can turn-on farther down the attenuation curve, once the attenuation stage has already turned from a maximum attenuation toward a minimum attenuation.

Although the attenuator section 200 is shown to have a particular configuration and a specific number of components (e.g., FETs and resistors), it should be appreciated that embodiments of the present disclosure are not so limited. Indeed, embodiments of the present disclosure contemplate that the attenuator section 200 may include a greater or fewer number of transistors and/or resistors.

In prior VVA control circuitry, attenuator sections 124 may be substantially identical and a reference voltage is divided down a resistor ladder. Each tap drives a differential amplifier input. The second input of each attenuator section 124 is driven by the control voltage. The differential amplifier outputs drive the series and shunt branches of the attenuator sections 124. All the stages are at full attenuation when the control line is low. When the control voltage goes up, the attenuation sections 124 move to low attenuation, progressively, from right to left.

In accordance with at least some embodiments of the present disclosure, two control lines are added per attenuation stage 200. These additional control lines control the FETs (e.g., FET10 and FET11) that will reduce insertion loss once the attenuation stage has moved from maximum attenuation towards the minimum attenuation. In the example illustrated in FIG. 3, the two control lines are tied together and offset by at least two stages towards the left. This offset helps ensure the attenuation stages 200 have already moved from higher to lower attenuation.

In accordance with at least some embodiments of the present disclosure, the circuit 300 includes a plurality of attenuator sections 200a-h, each of which may be connected in series with one another between the circuit input 104 and the circuit output 112. As noted above, each of the attenuator sections 200a-h may include circuitry to reduce a minimum insertion loss thereof (e.g. include multiple multi-FET branches). While the circuit 300 is shown to include eight attenuator sections 200a-h, it should be appreciated that the circuit 300 may include a greater or fewer number of attenuator sections 200a-h without departing from the scope of the present disclosure. Specifically, but without limitation, the circuit 300 may include as few as two attenuator sections 200 and as many as three, four, five, six, seven, eight, nine, ten, . . . , twenty, or more attenuator sections 200.

The circuit 300 may also include a control circuit for the plurality of attenuator sections 200a-h. In some embodiments, each attenuator section 200a-h is controlled by two different control signals as compared to the single control signal used to control attenuator sections 124. Each attenuator section 200a-h may be provided with a first control signal and a second control signal from different control stages 304a-j in the control circuit. In other words, each attenuator section 200a-h may be controlled by two separate control stages 304a-j such that each of the attenuator sections 200a-h receives a first control signal and a second control signal. According to at least some embodiments, the first control signal switches an attenuator section 200 between an on and off state. The second control signal may improve linearity of the attenuator section 200 as it transitions between the on and off state. In some embodiments, the second control signal is applied to a corresponding attenuator section 200 as the corresponding attenuator section moves along an attenuation curve between a maximum attenuation to a minimum attenuation. In some embodiments, the second control signal is applied to an attenuator section 200 before the attenuator section has reached a minimum attenuation. The second control signal may be timed with respect to the first control signal such that the second control signal is applied after the first control signal and while the corresponding attenuator section 200 is moving toward a minimum attenuation. The second control signal may be provided to one or more transistors in a shunt branch of the attenuator section 200 and the linearity of the attenuator section 200 is improved by reducing an insertion loss of the attenuator section 200 once the attenuator section 200 has moved away from a maximum attenuation.

The number of control stages 304a-j may be greater than the number of attenuator sections 200a-h. In the example of FIG. 3, there are two more control stages 304a-j than attenuator sections 200a-h. It should be appreciated that there may be only one more control stages 304a-j than attenuator sections 200a-h.

In some embodiments, the plurality of attenuator sections 200a-h includes at least a first attenuator section 200a and at least a second attenuator section 200b. The plurality of control stages 304a-j may include at least a first control stage 304a, at least a second control stage 304b, at least a third control stage 304c, and at least a fourth control stage 304d. In the depicted example, the first attenuator section 200a is controlled by the first control stage 304a and the third control stage 304c. The second attenuator section 200b is controlled by the second control stage 304b and the fourth control stage 304d. As shown in FIG. 3, the first control stage 304a is separated from the third control stage 304c by the second control stage 304b such that the first attenuator section 200a receives the second control signal from the third control stage 304c after the second attenuator section 200b receives the first control signal from the second control stage 304b. In some embodiments, each control stage 304a-j includes a differential amplifier. The differential amplifier that provides the second control signal to an attenuator section 200a-h may be provided at least two stages behind the attenuator section 200a-h to ensure that the second control signal is appropriately timed relative to the first control signal.

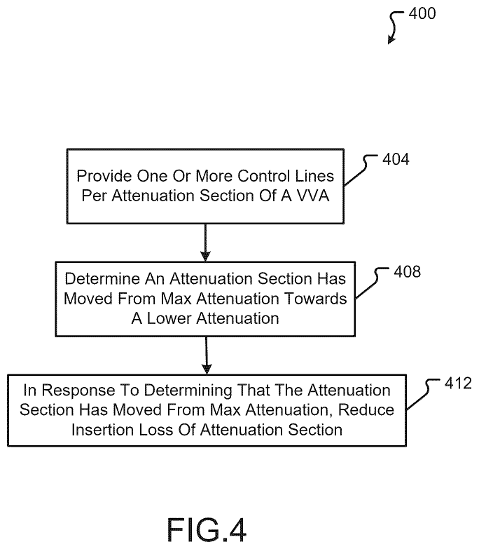

Referring now to FIG. 4, a method 400 will be described in accordance with at least some embodiments of the present disclosure. The method 400 may be used to control a circuit, such as circuit 300, using one or more control signals. In some embodiments, the method 400 may be performed using a plurality of differential amplifiers in a control circuit, where the various differential amplifiers belong to separate control stages 304a-j of the control circuit.

According to at least some embodiments, the method 400 begins by providing one or more control lines to each attenuation stage 200 of a VVA (step 404). In particular, and without departing from the scope of the present disclosure, each attenuation stage 200 may be provided with control signals from two or more different control stages 304a-j of the control circuit.

In some embodiments, the plurality of attenuator sections 200a-h may be controlled with a plurality of control stages 304a-j, where each of the plurality of attenuator sections 200a-h is controlled by two separate control stages in the plurality of control stages 304a-j such that each of the plurality of attenuator sections 304a-j receives a first control signal and a second control signal. In some embodiments, the first control signal switches an attenuator section 200 between an on and off state. In some embodiments, the second control signal improves linearity of the attenuator section 200 as it transitions between the on and off state.

Thus, the method 400 may continue by determining that an attenuation section (e.g., a first attenuation stage 200a or some other attenuation stage 200b-h) has moved from a maximum attenuation towards a lower attenuation (step 408). In some embodiments, this step may involve determining that the attenuation section 200 is moving along an attenuation curve and is neither at a maximum attenuation nor a minimum attenuation.

In response to determining that the attenuation section 200 is moving from the maximum attenuation, the method 400 may continue by reducing an insertion loss of the attenuation section 200 (step 412). In some embodiments, this step may involve providing the second control signal to the attenuation section 200 after determining that the attenuation section 200 is moving away from the maximum attenuation and before the attenuation section 200 has reached a minimum attenuation.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A circuit, comprising:
a plurality of attenuator sections, each of the plurality of attenuator sections connected in series with one another between a circuit input and a circuit output, wherein each of the plurality of attenuator sections comprises circuitry to reduce a minimum insertion loss thereof, the circuitry comprising a series branch of transistors, a shunt branch of transistors, and at least one additional branch of transistors connected in parallel with one or both of the series branch of transistors and the shunt branch of transistors, wherein the at least one additional branch of transistors is controllable independent of the series branch of transistors and the shunt branch of transistors; and
a control circuit for the plurality of attenuator sections, wherein the control circuit provides at least two control signals to each of the plurality of attenuator sections, wherein a first control signal is provided to one or both of the series branch of transistors and the shunt branch of transistors in an attenuator section to move the attenuator section between an on and off state, and wherein a second control signal is provided to the at least one additional branch of transistors to improve insertion loss of the attenuator section as it transitions between the on and off state.

2. The circuit of claim 1, wherein the second control signal is provided to one or more transistors in the shunt branch of transistors of the attenuator section and wherein the insertion loss of the attenuator section is improved by reducing an insertion loss of the attenuator section once the attenuator section has moved away from a maximum attenuation.

3. The circuit of claim 2, wherein the second control signal is timed with respect to the first control signal such that the second control signal is applied after the first control signal and while the attenuator section is moving toward a minimum attenuation.

4. The circuit of claim 2, wherein the control circuit comprises a plurality of differential amplifiers and wherein a first differential amplifier in the plurality of differential amplifiers that is used to control the attenuator section is at least two stages behind the attenuator section to ensure that the second control signal is appropriately timed relative to the first control signal.

5. The circuit of claim 2, wherein the second control signal is applied before the attenuator section has reached a minimum attenuation.

6. The circuit of claim 1, wherein the series branch of transistors comprises two or more transistors, wherein the shunt branch of transistors comprises two or more transistors, wherein the series branch of transistors doubles a resistance of a single transistor in the on state, and wherein the shunt branch of transistors provides a capacitance in the off state.

7. The circuit of claim 1, wherein a number of stages in the control circuit is at least one greater than a number of stages in the plurality of attenuator sections.

8. The circuit of claim 1, wherein a number of stages in the control circuit is at least two greater than a number of stages in the plurality of attenuator sections.

9. The circuit of claim 1, wherein the second control signal is applied to the attenuator section as the attenuator section moves along an attenuation curve between a maximum attenuation to a minimum attenuation.

10. A system, comprising:
a plurality of attenuator sections, each of the plurality of attenuator sections connected in series with one another between a circuit input and a circuit output, wherein each of the plurality of attenuator sections comprises circuitry to reduce a minimum insertion loss thereof, the circuitry comprising a series branch of transistors, a shunt branch of transistors, and at least one additional branch of transistors connected in parallel with one or both of the series branch of transistors and the shunt branch of transistors, wherein the at least one additional branch of transistors is controllable independent of the series branch of transistors and the shunt branch of transistors; and
a control circuit for the plurality of attenuator sections, wherein the control circuit comprises a plurality of control stages, wherein each of the plurality of attenuator sections is controlled by two separate control stages in the plurality of control stages such that each of the plurality of attenuator sections receives a first control signal and a second control signal, wherein the first control signal is provided to one or both of the series branch of transistors and the shunt branch of transistors in an attenuator section to move the attenuator section between an on and off state, and wherein the second control signal is provided to the at least one additional branch of transistors to improve insertion loss of the attenuator section as it transitions between the on and off state.

11. The system of claim 10, wherein a number of stages in the plurality of control stages is at least one greater than a number of attenuator sections in the plurality of attenuator sections.

12. The system of claim 10, wherein a number of stages in the plurality of control stages is at least two greater than a number of attenuator sections in the plurality of attenuator sections.

13. The system of claim 10, wherein the plurality of attenuator sections comprises at least a first attenuator section and at least a second attenuator section, wherein the plurality of control stages comprises at least a first control stage, at least a second control stage, at least a third control stage, and at least a fourth control stage, wherein the at least a first attenuator section is controlled by the at least a first control stage and the at least a third control stage, wherein the at least a second attenuator section is controlled by the at least a second control stage and the at least a fourth control stage, and wherein the at least a first control stage is separated from the at least a third control stage by the at least a second control stage such that the at least a first attenuator section receives the second control signal from the at least a third control stage after the at least a second attenuator section receives the first control signal from the at least a second control stage.

14. The system of claim 10, wherein the second control signal is provided to one or more transistors in the shunt branch of transistors of the attenuator section and wherein the insertion loss of the attenuator section is improved by reducing an insertion loss of the attenuator section once the attenuator section has moved away from a maximum attenuation.

15. The system of claim 14, wherein the second control signal is timed with respect to the first control signal such that the second control signal is applied after the first control signal and while the attenuator section is moving toward a minimum attenuation.

16. The system of claim 14, wherein each control stage comprises a differential amplifier and wherein a first differential amplifier that is used to control the attenuator section is at least two stages behind the attenuator section to ensure that the second control signal is appropriately timed relative to the first control signal.

17. The system of claim 14, wherein the second control signal is applied before the attenuator section has reached a minimum attenuation.

18. A method, comprising:
providing a plurality of attenuator sections, each of the plurality of attenuator sections connected in series with one another between a circuit input and a circuit output, wherein each of the plurality of attenuator sections comprises circuitry to reduce a minimum insertion loss thereof, the circuitry comprising a series branch of transistors, a shunt branch of transistors, and at least one additional branch of transistors connected in parallel with one or both of the series branch of transistors and the shunt branch of transistors, wherein the at least one additional branch of transistors is controllable independent of the series branch of transistors and the shunt branch of transistors; and
controlling the plurality of attenuator sections with a plurality of control stages, wherein each of the plurality of attenuator sections is controlled by two separate control stages in the plurality of control stages such that each of the plurality of attenuator sections receives a first control signal and a second control signal, wherein the first control signal is provided to one or both of the series branch of transistors and the shunt branch of transistors in an attenuator section to move the attenuator section between an on and off state, and wherein the second control signal is provided to the at least one additional branch of transistors to improve insertion loss of the attenuator section as it transitions between the on and off state.

19. The method of claim 18, further comprising:
determining that the attenuator section is transitioning from a maximum attenuation; and
in response to determining that the attenuator section is transitioning from the maximum attenuation, providing the second control signal.

20. The method of claim 19, wherein the second control signal is provided to the attenuator section before the attenuator section has reached a minimum attenuation.
